(19) United States
(12) Patent Application Publication
(10) Pub. No.: US 2026/0361050 A1
(43) Pub. Date: Nov. 12, 2026

(54) OPTICAL MODULATOR INTEGRATED LASER DEVICE

(71) Applicant: SUMITOMO ELECTRIC DEVICE INNOVATIONS, INC., Yokohama-shi, Kanagawa (JP)

(72) Inventor: Hiromitsu KAWAMURA, Kanagawa (JP)

(73) Assignee: SUMITOMO ELECTRIC DEVICE INNOVATIONS, INC., Yokohama-shi, Kanagawa (JP)

(21) Appl. No.: 19/673,417

(22) Filed: May 11, 2026

(30) Foreign Application Priority Data
May 12, 2025 (JP) 2025-079687

(51) Int. Cl. H01S 5/026; G02F 1/17

(52) U.S. Cl. CPC H01S 5/0265; G02F 1/17

(57) ABSTRACT

An optical modulator integrated laser device includes: a laser unit that is provided on a substrate and configured to output laser light; and an electro-absorption type first optical modulator that is provided on the substrate and configured to modulate the laser light output from the laser unit with a first modulation signal. The laser unit has an anode electrode to which a reference potential is input and a cathode electrode to which a bias voltage having a potential lower than the reference potential is input.

### CROSS REFERENCE TO RELATED APPLICATION

Priority is claimed on Japanese Patent Application No. 2025-079687 filed on May 12, 2025, the entire content of which is incorporated herein by reference.

### TECHNICAL FIELD

The present disclosure relates to an optical modulator integrated laser device.

### BACKGROUND

Japanese Unexamined Patent Publication No. 2002-277840 discloses an optical modulator integrated laser device that includes a laser unit and an electro-absorption type optical modulator. The optical modulator includes an n-electrode and a p-electrode. A positive-phase signal and an inverted-phase signal that form a differential signal are input to the n-electrode and the p-electrode, respectively.

### SUMMARY

An optical modulator integrated laser device according to an aspect of the present disclosure includes: a laser unit that is provided on a substrate and outputs laser light; and an electro-absorption type first optical modulator that is provided on the substrate and modulates the laser light output from the laser unit with a first modulation signal. The laser unit has an anode electrode to which a reference potential is input and a cathode electrode to which a bias voltage having a potential lower than the reference potential is input.

### BRIEF DESCRIPTION OF THE DRAWINGS

FIG. 1 is a plan view showing an optical modulator integrated laser device according to an embodiment of the present disclosure.

FIG. 2 is a drawing schematically showing a cross section taken along the line II-II shown in FIG. 1.

FIG. 3 is a drawing schematically showing a cross section taken along the line III-III shown in FIG. 1.

FIG. 4 is a drawing schematically showing a cross section taken along the line IV-IV shown in FIG. 1.

FIG. 5 is a drawing schematically showing a cross section taken along the line V-V shown in FIG. 1.

FIG. 6 is a circuit diagram of the laser device and its peripheral circuits according to the embodiment.

FIG. 7 is a graph showing the time waveform of a first modulation signal applied to the optical modulator.

FIG. 8 is a plan view showing a laser device according to a first modification.

FIG. 9 is a circuit diagram showing the laser device according to the first modification and its peripheral circuits.

FIG. 10 is a plan view showing a laser device according to a second modification.

FIG. 11 is a circuit diagram showing the laser device according to the second modification and its peripheral circuits.

FIG. 12 is a plan view showing a laser device according to a third modification.

FIG. 13 is a drawing schematically showing a cross section taken along the line XIII-XIII shown in FIG. 12.

FIG. 14 is a plan view showing a laser device according to a fourth modification.

FIG. 15 is a drawing schematically showing a cross section taken along the line XV-XV shown in FIG. 14.

FIG. 16 is a circuit diagram showing a laser device according to a fifth modification and its peripheral circuits.

FIG. 17 is a plan view showing a laser device according to a sixth modification.

FIG. 18 is a circuit diagram showing the laser device according to the sixth modification and its peripheral circuits.

FIG. 19 is a graph showing the time waveforms of a first modulation signal and a second modulation signal applied to the optical modulator.

FIG. 20 is a plan view showing a laser device according to a seventh modification.

FIG. 21 is a circuit diagram showing the laser device according to the seventh modification and its peripheral circuits.

FIG. 22 is a plan view showing a laser device according to an eighth modification.

FIG. 23 is a circuit diagram showing the laser device according to the eighth modification and its peripheral circuits.

FIG. 24 is a plan view showing a laser device according to a ninth modification.

FIG. 25 is a plan view showing a laser device according to a tenth modification.

FIG. 26 is a plan view showing a laser device according to an eleventh modification.

FIG. 27 is a plan view showing a laser device according to a comparative example.

### DETAILED DESCRIPTION

An object of the present disclosure is to provide an optical modulator integrated laser device capable of improving the quality of an optical signal.

### Description of Embodiments of Present Disclosure

First, the contents of embodiments of the present disclosure will be listed and described.
[1] An optical modulator integrated laser device according to one embodiment of the present disclosure includes: a laser unit that is provided on a substrate and outputs laser light; and an electro-absorption type first optical modulator that is provided on the substrate and modulates the laser light output from the laser unit with a first modulation signal. The laser unit has an anode electrode to which a reference potential is input and a cathode electrode to which a bias voltage having a potential lower than the reference potential is input.
[2] In the optical modulator integrated laser device according to [1] above, the first optical modulator may have an anode electrode to which the reference potential is input and a cathode electrode to which the first modulation signal is input.
[3] In the optical modulator integrated laser device according to [2] above, a trench reaching the substrate may be formed to surround the cathode electrode of the first optical modulator.
[4] In the optical modulator integrated laser device according to [2] or [3] above, the laser unit and the first optical modulator may be optically coupled by an optical waveguide, and the anode electrode of the laser unit may be connected to the anode electrode of the first optical modulator on the optical waveguide.
[5] In the optical modulator integrated laser device according to any one of [1] to [4] above, an electrode pad having the reference potential may be arranged between the laser unit and the first optical modulator.
[6] The optical modulator integrated laser device according to any one of [2] to [5] above may further include a first terminator provided on the substrate and having a first resistive film. The first terminator may be connected between the anode electrode of the first optical modulator and the cathode electrode of the first optical modulator.
[7] The optical modulator integrated laser device according to any one of [1] to [6] above may further include an electro-absorption type second optical modulator provided on the substrate downstream of the first optical modulator. The second optical modulator may have an anode electrode to which a second modulation signal forming a differential signal together with the first modulation signal is input and a cathode electrode to which the reference potential is input.
[8] In the optical modulator integrated laser device according to [7] above, a trench reaching the substrate may be formed to surround the anode electrode of the second optical modulator.
[9] The optical modulator integrated laser device according to [7] or [8] above may further include a second terminator provided on the substrate and having a second resistive film. The second terminator may be connected between the anode electrode of the second optical modulator and the cathode electrode of the second optical modulator.
[10] In the optical modulator integrated laser device according to [1] above, the first optical modulator may have an anode electrode to which one of differential modulation signals is input and a cathode electrode to which the other of the differential modulation signals is input.

### Details of Embodiments of Present Disclosure

Specific examples of the present disclosure will be described below with reference to the drawings. The present disclosure is not limited to these examples, but is defined by the claims, and is intended to include all modifications within the meaning and scope equivalent to the claims. In the following description, the same elements will be denoted by the same reference numerals in the description of the drawings, and repeated description thereof will be omitted. In the following description, "connection" means electrical connection.

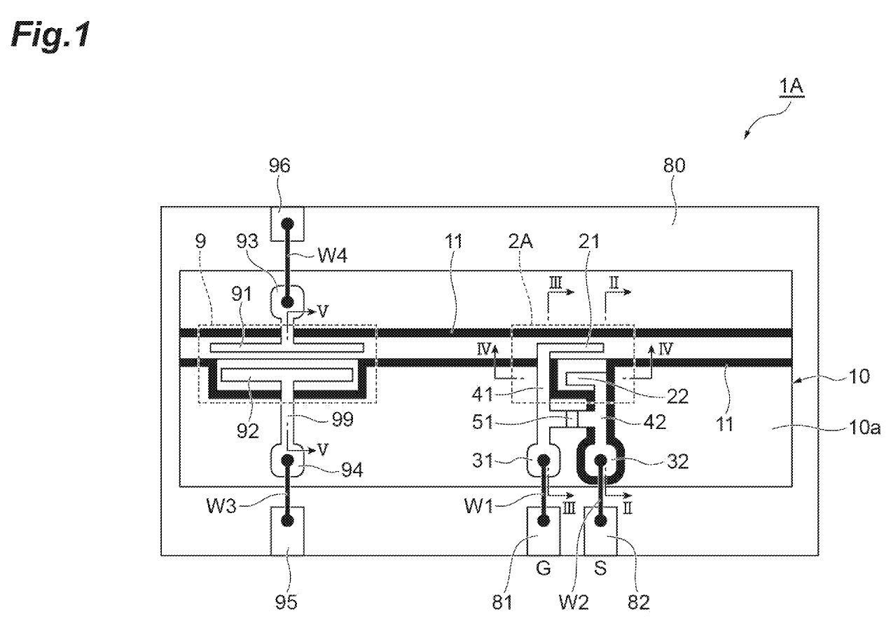

FIG. 1 is a plan view showing an optical modulator integrated laser device (hereinafter, simply referred to as a laser device) 1A according to an embodiment of the present disclosure. The laser device 1A according to the present embodiment includes a substrate 10, an optical modulator 2A (first optical modulator), and a laser unit 9. The optical modulator 2A and the laser unit 9 are monolithically provided on the common substrate 10. The optical modulator 2A and the laser unit 9 are adjacent to each other along an optical waveguide direction on the substrate 10. The laser unit 9 outputs laser light. The optical modulator 2A receives laser light from the laser unit 9. The substrate 10 is a semi-insulating or insulating substrate. In one example, the substrate 10 is a semi-insulating InP substrate.

The laser device 1A is mounted on a carrier 80. A bias pattern 95 and a ground pattern 96 are provided on the main surface of the carrier 80. In addition, a ground wiring pattern 81 and a signal wiring pattern 82 are provided on the main surface of the carrier 80. The laser device 1A is mounted on the main surface of the carrier 80, and the back surface of the laser device 1A is bonded to the main surface of the carrier 80. The ground wiring pattern 81, the signal wiring pattern 82, the bias pattern 95, and the ground pattern 96 are arranged at a peripheral portion of the laser device 1A.

The laser unit 9 has an anode electrode 91 and a cathode electrode 92. The anode electrode 91 and the cathode electrode 92 are electrodes for supplying a bias current to an active layer (not shown) of the laser unit 9. The anode electrode 91 and the cathode electrode 92 extend along the optical waveguide direction and are aligned in a direction crossing the optical waveguide direction. The laser device 1A further includes an electrode pad 93 (first electrode pad) and an electrode pad 94 (second electrode pad). The electrode pad 94 is a metal film provided on one side of the laser unit 9 on the substrate 10, and is connected to the cathode electrode 92 of the laser unit 9. The electrode pad 94 is connected to the bias pattern 95 through a bonding wire W3. A bias voltage having a potential lower than a reference potential is input to the electrode pad 94 from the bias pattern 95 through a bonding wire W3. The electrode pad 93 is a metal film provided on the substrate 10 and is connected to the anode electrode 91 of the laser unit 9. The electrode pad 93 is connected to the ground pattern 96 through a bonding wire W4. The reference potential is input to the electrode pad 93 from the ground pattern 96 through the bonding wire W4. As a result, the anode electrode 91 is set to the reference potential, and a bias current flows between the anode electrode 91 and the cathode electrode 92.

The optical modulator 2A is an electro-absorption (EA) type optical modulator, is provided on the substrate 10, and modulates the laser light output from the laser unit 9 with a first modulation signal. The optical modulator 2A has an anode electrode 21 and a cathode electrode 22. The anode electrode 21 and the cathode electrode 22 are electrodes for applying a modulation voltage to a light absorption layer (not shown) of the optical modulator 2A. The anode electrode 21 and the cathode electrode 22 extend along the optical waveguide direction and are aligned in a direction crossing the optical waveguide direction. The anode electrode 21 is set to the reference potential, and the first modulation signal having a potential higher than the reference potential is input to the cathode electrode 22.

The laser device 1A further includes an electrode pad 31 (third electrode pad) and an electrode pad 32 (fourth electrode pad). The electrode pad 31 is a metal film provided on one side (that is, the same side as the electrode pad 94) of the optical modulator 2A on the substrate 10, and is connected to the anode electrode 21 of the optical modulator 2A. The electrode pad 32 is a metal film provided on one side (that is, the same side as the electrode pad 31) of the optical modulator 2A on the substrate 10, and is connected to the cathode electrode 22 of the optical modulator 2A. The electrode pad 31 is connected to the ground wiring pattern 81 through a bonding wire W1. The reference potential is input to the electrode pad 31 from the ground wiring pattern 81 through the bonding wire W1. As a result, the anode electrode 21 is set to the reference potential. The electrode pad 32 is connected to the signal wiring pattern 82 through a bonding wire W2. The first modulation signal having a potential higher than the reference potential is input to the electrode pad 32 from the signal wiring pattern 82 through the bonding wire W2. As a result, a voltage based on the first modulation signal is applied between the anode electrode 21 and the cathode electrode 22.

The electrode pad 31 is arranged between the electrode pad 94 and the electrode pad 32 on one side of the laser unit 9 and the optical modulator 2A. That is, the electrode pad 94, the electrode pad 31, and the electrode pad 32 are aligned in this order along the optical waveguide direction. Therefore, the bonding wire W1, which is set to the reference potential, is located between the bonding wire W2 for transmitting the first modulation signal and the bonding wire W3 for supplying the bias voltage. The bonding wires W1, W2, and W3 extend in parallel with each other.

The electrode pad 31 is connected to the anode electrode 21 through a wiring 41 that is a metal film. The electrode pad 32 is connected to the cathode electrode 22 through a wiring 42 that is a metal film. The electrode pad 94 is connected to the cathode electrode 92 through a wiring 99 that is a metal film. The wirings 41, 42, and 99 extend in a direction crossing the optical waveguide direction, and extend in parallel with each other. The wiring 41 is arranged between the wiring 99 and the wiring 42 in the optical waveguide direction.

A termination resistor 51 (first terminator) is provided between the wiring 41 and the wiring 42. A first end of the termination resistor 51 is connected to the wiring 41. A second end of the termination resistor 51 is connected to the wiring 42. The termination resistor 51 has a first resistive film provided on the substrate 10, and terminates the first modulation signal. As a result, the frequency characteristics of the first modulation signal are improved. The resistance value of the termination resistor 51 is determined according to the impedance of the optical modulator 2A. The arrangement of the termination resistor 51 is not limited to the present embodiment. For example, the termination resistor 51 may be provided on the carrier 80. The termination resistor 51 may be replaced with a CR circuit having a complex impedance.

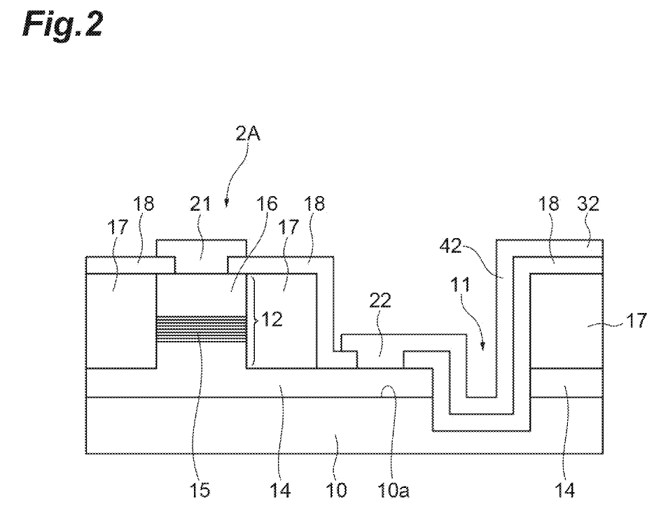

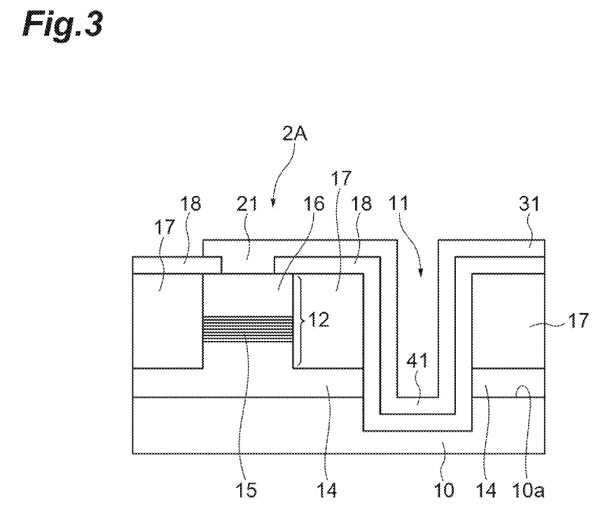

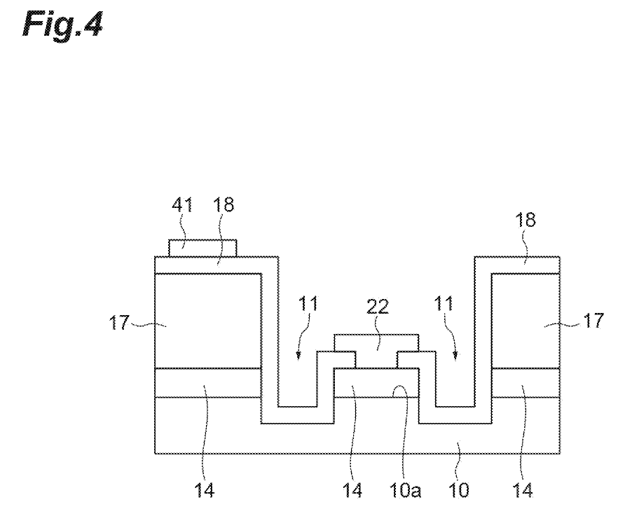

FIG. 2 is a drawing schematically showing a cross section taken along the line II-II shown in FIG. 1. FIG. 3 is a drawing schematically showing a cross section taken along the line III-III shown in FIG. 1. FIG. 4 is a drawing schematically showing a cross section taken along the line IV-IV shown in FIG. 1. The optical modulator 2A has a first cladding layer 14, a light absorption layer 15, and a second cladding layer 16. In the present embodiment, the first cladding layer 14, the light absorption layer 15, and the second cladding layer 16 are III-V compound semiconductor layers.

The first cladding layer 14 is an n-type semiconductor layer provided on a main surface 10a of the substrate 10. In one example, the first cladding layer 14 is an n-type InP layer. The light absorption layer 15 is provided on the first cladding layer 14. The band gap of the light absorption layer 15 is smaller than the band gap of the first cladding layer 14. The refractive index of the light absorption layer 15 is greater than the refractive index of the first cladding layer 14. The light absorption layer 15 may have a multiple quantum well structure. In one example, the light absorption layer 15 is formed by stacking InGaAsP layers or InGaAlAs layers having different compositions. The second cladding layer 16 is provided on the light absorption layer 15 and has p-type conductivity. In one example, the second cladding layer 16 is a p-type InP layer.

A part of the first cladding layer 14, the light absorption layer 15, and the second cladding layer 16 form a mesa structure 12 extending along the optical waveguide direction. The base of the mesa structure 12 is located in the first cladding layer 14. Therefore, a lower portion of the first cladding layer 14 also extends outside the mesa structure 12 in plan view.

The optical modulator 2A further includes a burying region 17 and an insulating film 18. The burying region 17 is provided on both sides of the mesa structure 12, and buries both side surfaces of the mesa structure 12. The burying region 17 has insulating or semi-insulating properties. The burying region 17 is, for example, a semi-insulating InP region. The material of the burying region 17 may be the same as or different from the material of the substrate 10. The insulating film 18 is provided on the burying region 17 and covers the burying region 17. The insulating film 18 is, for example, a silicon compound film such as SiO₂ or SiN.

The anode electrode 21 is provided on the mesa structure 12 of the optical modulator 2A and is connected to the second cladding layer 16 of the optical modulator 2A. The reference potential input from the electrode pad 31 to the anode electrode 21 through the wiring 41 is transmitted to the second cladding layer 16 of the optical modulator 2A. The cathode electrode 22 is provided on the first cladding layer 14 on a lateral side of the mesa structure 12 of the optical modulator 2A and is connected to the first cladding layer 14 of the optical modulator 2A. The first modulation signal input from the electrode pad 32 to the cathode electrode 22 through the wiring 42 is transmitted to the first cladding layer 14 of the optical modulator 2A.

The optical modulator 2A further has a pair of trenches (grooves) 11. The pair of trenches 11 extend from the upper surface of the second cladding layer 16 to the substrate 10, and electrically isolate the optical modulator 2A from surrounding semiconductor layers. In FIG. 1, the trenches 11 are indicated by thick lines. The mesa structure 12 of the optical modulator 2A is provided between the pair of trenches 11. One of the pair of trenches 11 bulges outward so that a portion of the first cladding layer 14 connected to the cathode electrode 22 is included between the pair of trenches 11. Inner surfaces of the trenches 11 are covered with the insulating film 18. In addition, when viewed in the thickness direction of the substrate 10, the trench 11 is also formed between a region of the semiconductor layer overlapping the electrode pad 32 and a region of the semiconductor layer surrounding the electrode pad 32. The trench 11 completely surrounds the electrode pad 32 when viewed in the thickness direction of the substrate 10. The wiring 42 crosses the trench 11 by running along a sidewall and a bottom surface of the trench 11 between the electrode pad 32 and the cathode electrode 22.

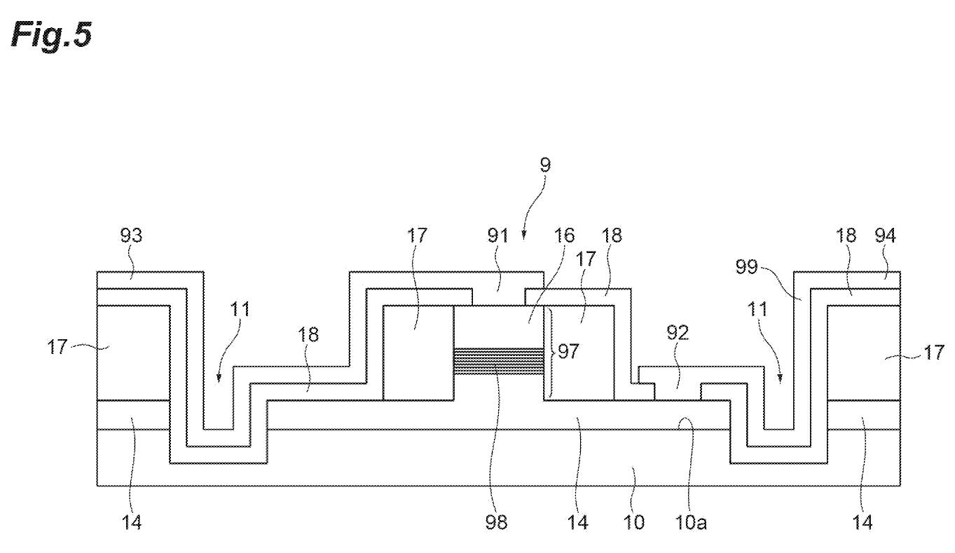

FIG. 5 is a drawing schematically showing a cross section taken along the line V-V shown in FIG. 1. The laser unit 9 includes the first cladding layer 14, an active layer 98, and the second cladding layer 16. In the present embodiment, the first cladding layer 14, the active layer 98, and the second cladding layer 16 are III-V compound semiconductor layers. The configurations of the first cladding layer 14 and the second cladding layer 16 are the same as those of the optical modulator 2A.

The active layer 98 is provided on the first cladding layer 14. The bandgap of the active layer 98 is smaller than the bandgap of the first cladding layer 14. The refractive index of the active layer 98 is greater than the refractive index of the first cladding layer 14. The active layer 98 may have a multiple quantum well structure. In one example, the active layer 98 is formed by stacking InGaAsP layers or InGaAlAs layers having different compositions. The second cladding layer 16 is provided on the active layer 98. A part of the first cladding layer 14, the active layer 98, and the second cladding layer 16 form a mesa structure 97 extending along the optical waveguide direction.

The anode electrode 91 is provided on the mesa structure 97 of the laser unit 9 and is connected to the second cladding layer 16 of the laser unit 9. The reference potential input from the electrode pad 93 to the anode electrode 91 is transmitted to the second cladding layer 16 of the laser unit 9. The cathode electrode 92 is provided on the first cladding layer 14 on a lateral side of the mesa structure 97 of the laser unit 9 and is connected to the first cladding layer 14 of the laser unit 9. The bias voltage input from the electrode pad 94 to the cathode electrode 92 through the wiring 99 is transmitted to the first cladding layer 14 of the laser unit 9.

The laser unit 9 also has a pair of trenches 11. The mesa structure 97 of the laser unit 9 is provided between the pair of trenches 11. One of the pair of trenches 11 bulges outward so that a portion of the first cladding layer 14 connected to the cathode electrode 92 is included between the pair of trenches 11.

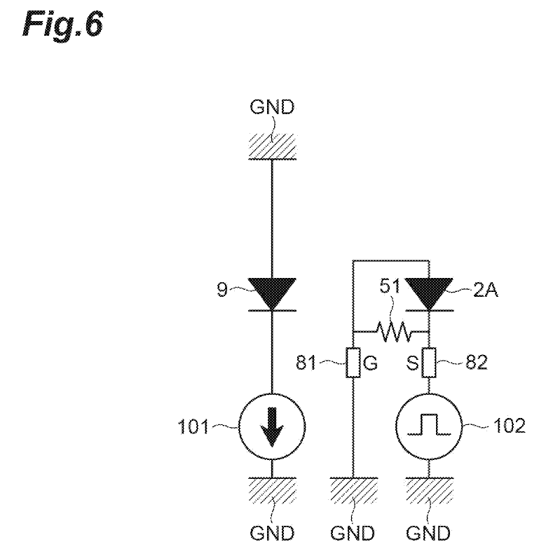

FIG. 6 is a circuit diagram of the laser device 1A and its peripheral circuits according to the present embodiment. In FIG. 6, the laser unit 9 and the optical modulator 2A are indicated by diode symbols. As shown in FIG. 6, a bias current source 101 that generates a bias current is connected between the cathode of the laser unit 9 and the reference potential line GND. The anode of the laser unit 9 is connected to the reference potential line GND. The bias current source 101 applies a bias voltage having a potential lower than the potential of the reference potential line GND to the cathode of the laser unit 9. A signal source 102 that generates a first modulation signal is connected between the cathode of the optical modulator 2A and the reference potential line GND. The signal source 102 supplies the first modulation signal having a potential higher than the potential of the reference potential line GND to the cathode of the optical modulator 2A through the signal wiring pattern 82. The anode of the optical modulator 2A is connected to the reference potential line GND through the ground wiring pattern 81.

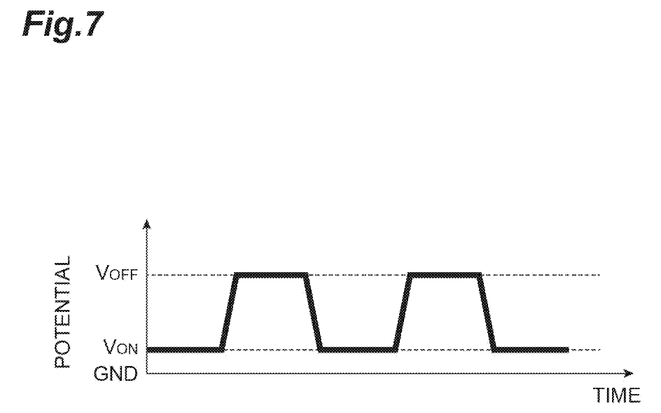

FIG. 7 is a graph showing the time waveform of the first modulation signal applied to the optical modulator 2A. As shown in FIG. 7, the first modulation signal changes between a potential V_{OFF} and a potential V_{ON} that is lower than the potential V_{OFF}. The optical modulator 2A absorbs the laser light when the first modulation signal has the potential V_{ON}, and allows the laser light to pass therethrough when the first modulation signal has the potential V_{OFF}. The potential V_{OFF} and the potential V_{ON} of the first modulation signal are higher than the reference potential (indicated as GND in the drawing). The reference potential is, for example, 0.0 V. The reference potential may be any potential other than 0.0 V (GND), such as -0.2 V, -0.5 V, +0.2 V, or +0.3 V, as long as this is a potential maintained constant.

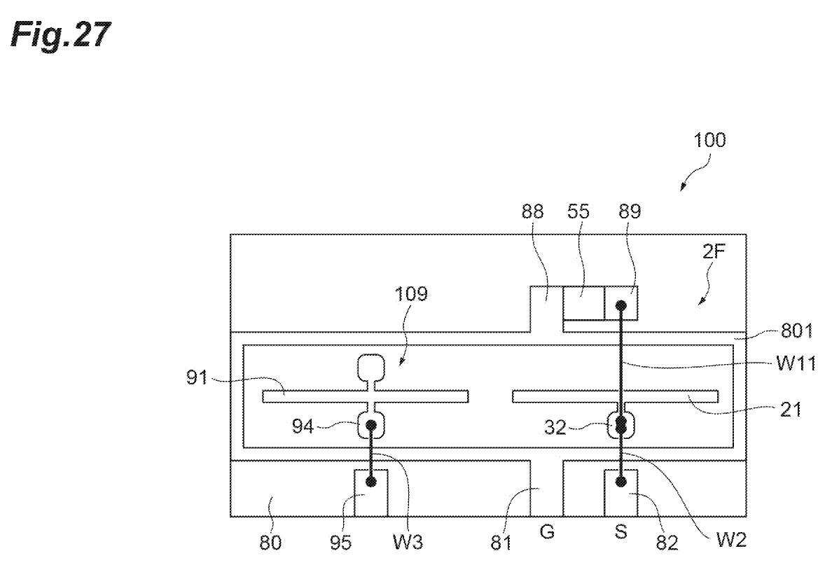

The effects obtained by the laser device 1A according to the present embodiment described above will be described together with problems encountered in a comparative example. FIG. 27 is a plan view showing a laser device 100 according to a comparative example. The laser device 100 includes an optical modulator 2F and a laser unit 109. The carrier 80 has a ground pattern 801 formed integrally with the ground wiring pattern 81 on its main surface. In the laser unit 109, a cathode electrode is provided on the back surface of the substrate and is conductively bonded to the ground pattern 801. The anode electrode 91 of the laser unit 109 is connected to the electrode pad 94 and receives a bias voltage from the bias pattern 95 through the bonding wire W3 and the electrode pad 94. In this comparative example, the potential of the bias voltage is higher than the reference potential. The cathode electrode of the optical modulator 2F is provided on the back surface of the substrate and is conductively bonded to the ground pattern 801. The electrode pad 32 is connected to a signal pattern 89 provided on the carrier 80 through a bonding wire W11. The signal pattern 89 is connected to a ground wiring pattern 88, which is formed integrally with the ground pattern 801 on the carrier 80, through a termination resistor 55.

In recent years, in optical communication systems using an optical modulator integrated laser device, the speed of the modulation signal has been increasing in order to increase transmission capacity. However, when the speed of the modulation signal increases, in a structure such as the laser device 100, the modulation signal propagating through the bonding wire W2 tends to interfere with the bias current flowing through the bonding wire W3. This is because mutual inductance is generated between the inductance of the bonding wire W2 and the inductance of the bonding wire W3 and accordingly, the modulation signal propagating through the bonding wire W2 is transmitted to the bonding wire W3. As a result, fluctuations occur in the bias current supplied to the laser unit 109, causing wavelength fluctuations in the laser light output from the laser unit 109. Such wavelength fluctuations cause optical waveform degradation after transmission due to wavelength dispersion in the optical fiber during long-distance transmission. This leads to a degradation in communication quality measured by using indices such as transmitter and dispersion eye closure (TDECQ).

To address such problems, in the optical modulator 2A according to the present embodiment, the electrode pad 31 for transmitting the reference potential is arranged between the electrode pad 94 for transmitting the bias current of the laser unit 9 and the electrode pad 32 for transmitting the first modulation signal. For this reason, the bonding wire W1 for transmitting the reference potential is inevitably arranged between the bonding wire W3 for transmitting the bias current and the bonding wire W2 for transmitting the first modulation signal. In addition, the wiring 41 for transmitting the reference potential is arranged between the wiring 99 for transmitting the bias current and the wiring 42 for transmitting the first modulation signal. Therefore, since the first modulation signal is shielded by the reference potential line (the bonding wire W1, the electrode pad 31, the wiring 41, and the anode electrode 21), the first modulation signal is less likely to interfere with the bias current. As a result, it is possible to reduce wavelength fluctuations occurring in the laser light and accordingly improve the quality of the optical signal.

The improvement in the quality of the optical signal is considered to be due to the fact that the anode electrode 21 (modulator anode region) of the optical modulator 2A is fixed at the reference potential to suppress potential fluctuation and accordingly, electric field radiation into space due to potential fluctuations is reduced.

On the other hand, since the cathode electrode 92 of the laser unit 9 is close to the substrate 10 (which is a semi-insulating substrate that is considered to be a resistive region), electric field radiation due to potential fluctuations is attenuated on the substrate 10 side, making it less susceptible to the influence of the modulation signal.

As in the present embodiment, the trench 11 reaching the substrate 10 may be formed between a region of the semiconductor layer overlapping the electrode pad 32 and a region of the semiconductor layer surrounding the electrode pad 32 when viewed in the thickness direction of the substrate 10. This makes it easier for the cathode of the optical modulator 2A and the cathode of the laser unit 9 to be electrically isolated from each other by the trench 11. Therefore, it is possible to further suppress the interference of the first modulation signal with the bias current and further improve the quality of the optical signal.

### First Modification

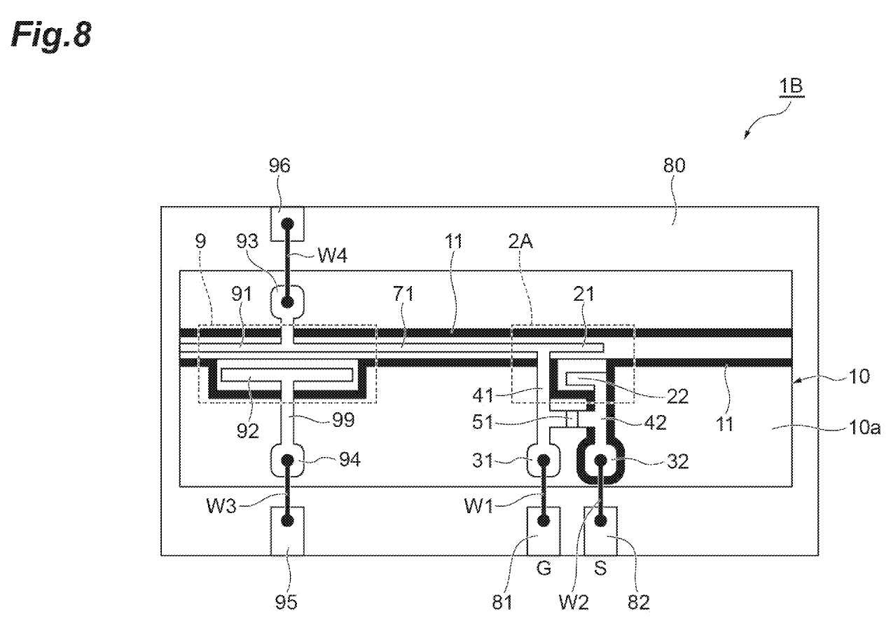

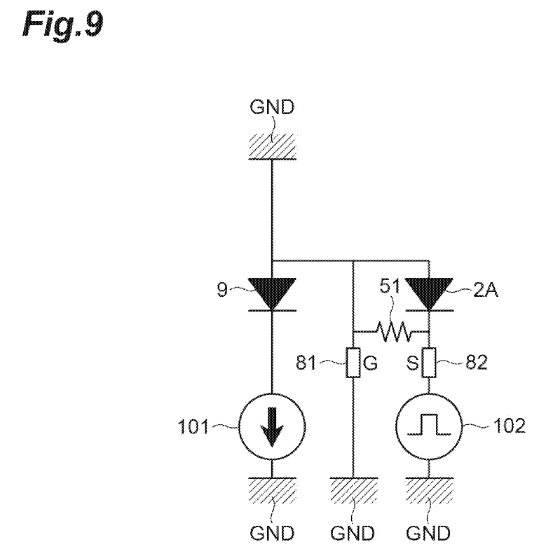

FIG. 8 is a plan view showing a laser device 1B according to a first modification of the above embodiment. FIG. 9 is a circuit diagram showing the laser device 1B according to this modification and its peripheral circuits. The laser device 1B according to this modification is different from the laser device 1A according to the above embodiment in the following points, but is the same as the laser device 1A in other points.

In the laser device 1B, the anode electrode 91 of the laser unit 9 is connected to the anode electrode 21 of the optical modulator 2A through a wiring 71 provided on the optical waveguide (on the mesa structure). According to such a structure, when viewed in the thickness direction of the substrate 10, the electrode pad 94 and the wiring 99 through which the bias current flows can be substantially surrounded by the anode electrode 91, the wiring 71, the wiring 41, and the electrode pad 31, which have the reference potential. In this manner, the interference of the first modulation signal with the bias current is further suppressed, making it possible to further improve the quality of the optical signal.

### Second Modification

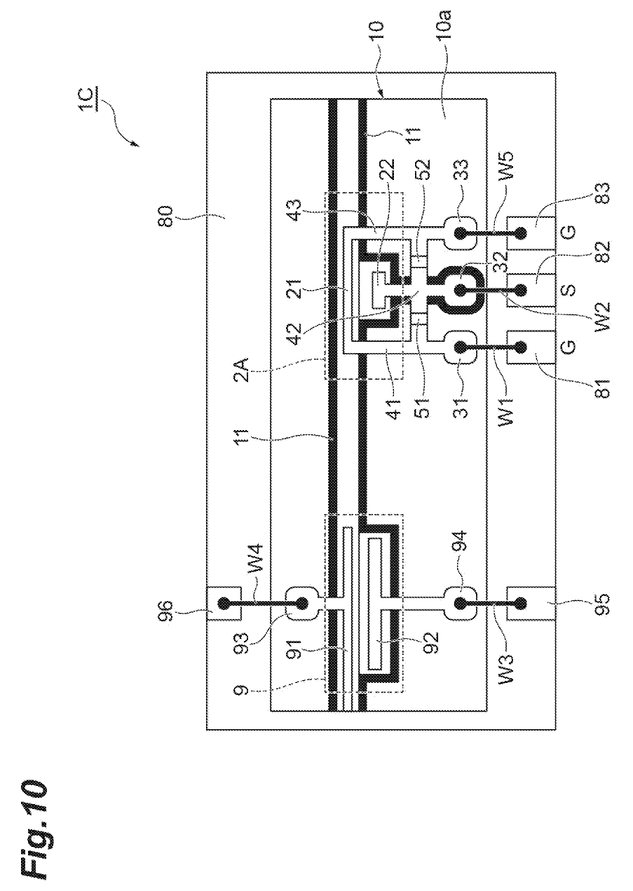

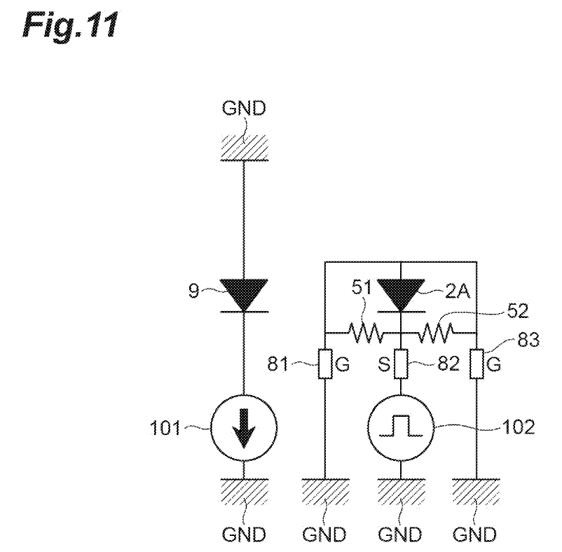

FIG. 10 is a plan view showing a laser device 1C according to a second modification of the above embodiment. FIG. 11 is a circuit diagram showing the laser device 1C according to this modification and its peripheral circuits. The laser device 1C according to this modification is different from the laser device 1A according to the above embodiment in the following points, but is the same as the laser device 1A in other points.

The laser device 1C further includes an electrode pad 33 and a wiring 43 provided on the substrate 10. The electrode pad 33 is provided on one side (the same side as the electrode pads 31 and 32) of the optical modulator 2A. The electrode pads 94, 31, 32, and 33 are aligned in this order along the optical waveguide direction. A ground wiring pattern 83 is further provided on the carrier 80. The electrode pad 33 is connected to the anode electrode 21 through the wiring 43 that is a metal film, and is also connected to the ground wiring pattern 83 through a bonding wire W5. The wiring 43 extends in a direction crossing the optical waveguide direction, and extends in parallel with the wirings 41 and 42. The wiring 42 is arranged between the wiring 41 and the wiring 43 in the optical waveguide direction. The reference potential is input to the electrode pad 33 from the ground wiring pattern 83 through the bonding wire W5. A termination resistor 52 is provided between the wiring 42 and the wiring 43. The wiring 43 is connected to the wiring 42 through the termination resistor 52. The arrangement of the termination resistor 52 is not limited to this modification. For example, the termination resistor 52 may be provided on the carrier 80. The termination resistor 52 may be replaced with a CR circuit having a complex impedance.

As in this modification, the electrode pad 32 may be provided between the electrode pads 31 and 33 for transmitting the reference potential. In this case, the bonding wire W2 for transmitting the first modulation signal is inevitably arranged between the bonding wires W1 and W5 for transmitting the reference potential. In addition, the wiring 42 for transmitting the first modulation signal is arranged between the wirings 41 and 43 for transmitting the reference potential. Therefore, since the propagation path of the first modulation signal is surrounded by the reference potential lines (the bonding wire W1, the wiring 41, the anode electrode 21, the wiring 43, and the bonding wire W5), the first modulation signal is even less likely to interfere with the bias current. As a result, wavelength fluctuations occurring in the laser light are further reduced, and accordingly, it is possible to further improve the quality of the optical signal.

### Third Modification

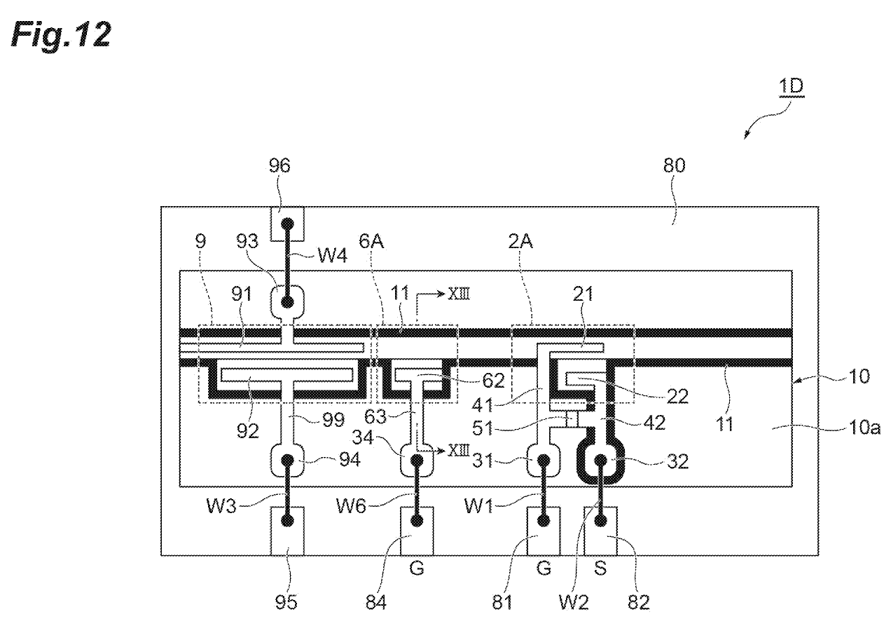

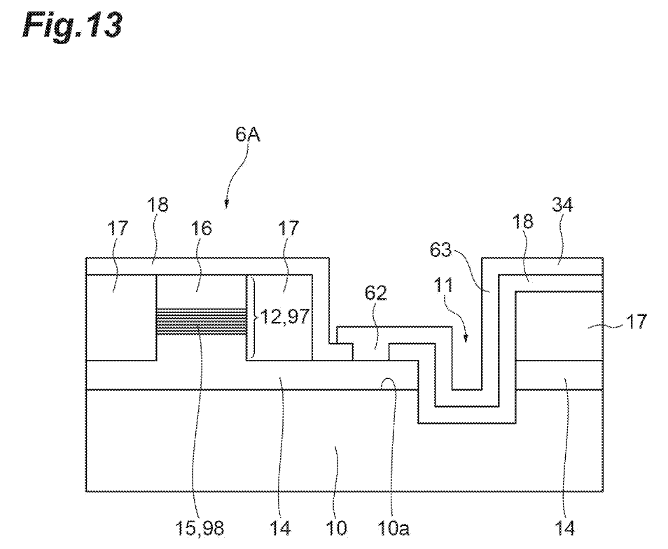

FIG. 12 is a plan view showing a laser device 1D according to a third modification of the above embodiment. FIG. 13 is a drawing schematically showing a cross section taken along the line XIII-XIII shown in FIG. 12. The laser device 1D according to this modification is different from the laser device 1A according to the above embodiment in the following points, but is the same as the laser device 1A in other points.

The laser device 1D further includes a potential setting section 6A and an electrode pad 34 provided on the substrate 10. The potential setting section 6A is provided on the optical path between the laser unit 9 and the optical modulator 2A. The potential setting section 6A has a cathode electrode 62. The cathode electrode 62 extends along the optical waveguide direction. The electrode pad 34 is a metal film provided on the substrate 10 on one side of the potential setting section 6A (that is, the same side as the electrode pads 94 and 31). The electrode pad 34 is connected to the cathode electrode 62 of the potential setting section 6A through a wiring 63 that is a metal film. The wiring 63 extends in a direction crossing the optical waveguide direction, and runs parallel to the wirings 42 and 99. The wiring 63 is arranged between the wiring 99 and the wiring 42 in the optical waveguide direction.

A ground wiring pattern 84 is further provided on the main surface of the carrier 80. The electrode pad 34 is connected to the ground wiring pattern 84 through a bonding wire W6. The reference potential is input to the electrode pad 34 from the ground wiring pattern 84 through the bonding wire W6. As a result, the cathode electrode 62 is set to the reference potential.

The electrode pad 34 is arranged between the electrode pad 94 and the electrode pad 31 on one side of the potential setting section 6A. That is, the electrode pad 94, the electrode pad 34, the electrode pad 31, and the electrode pad 32 are aligned in this order along the optical waveguide direction. Therefore, the bonding wires W1 and W6, which are set to the reference potential, are located between the bonding wire W2 for transmitting the first modulation signal and the bonding wire W3 for supplying the bias voltage. The bonding wires W1, W2, W3, and W6 extend in parallel with each other.

As shown in FIG. 13, the cathode electrode 62 is provided on the first cladding layer 14 on a lateral side of the mesa structure of the potential setting section 6A, and is connected to the first cladding layer 14 of the potential setting section 6A. The reference potential input from the electrode pad 34 to the cathode electrode 62 through the wiring 63 is transmitted to the first cladding layer 14 of the potential setting section 6A.

As in this modification, the potential setting section 6A may be provided on the optical path between the laser unit 9 and the optical modulator 2A, and the potential of the first cladding layer 14 of the potential setting section 6A may be set to the reference potential. In this case, it is possible to further increase the electrical isolation between the first cladding layer 14 of the laser unit 9 to which the bias voltage is applied and the first cladding layer 14 of the optical modulator 2A to which the first modulation signal is applied.

In addition, in this modification, two electrode pads 31 and 34 for transmitting the reference potential are arranged between the electrode pad 94 for transmitting the bias current and the electrode pad 32 for transmitting the first modulation signal. For this reason, two bonding wires W1 and W6 for transmitting the reference potential are inevitably arranged between the bonding wire W3 for transmitting the bias current and the bonding wire W2 for transmitting the first modulation signal. In addition, two wirings 41 and 63 for transmitting the reference potential are arranged between the wiring 99 for transmitting the bias current and the wiring 42 for transmitting the first modulation signal. Therefore, since the first modulation signal is more effectively shielded by the reference potential lines, the first modulation signal is even less likely to interfere with the bias current. As a result, wavelength fluctuations occurring in the laser light are further reduced, and accordingly, it is possible to further improve the quality of the optical signal.

### Fourth Modification

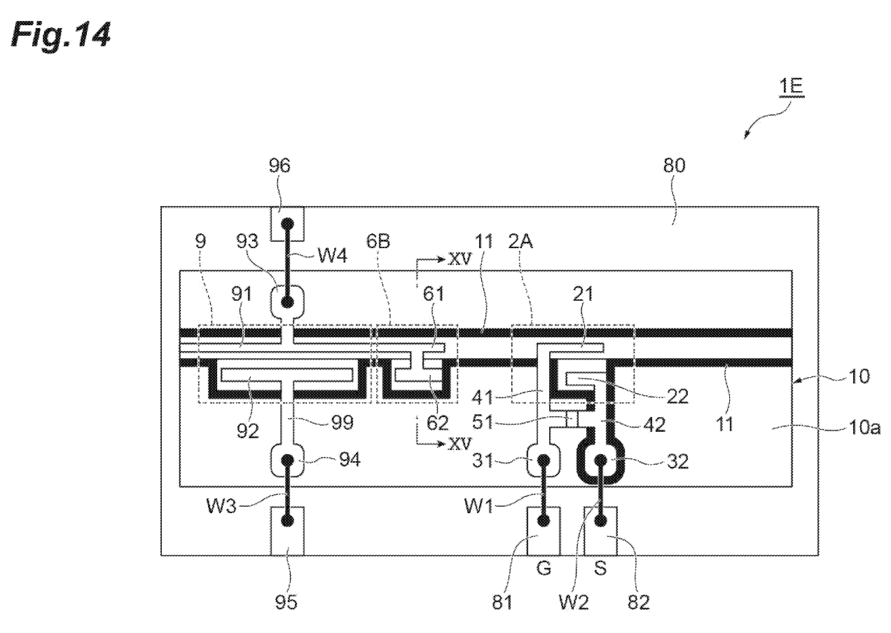

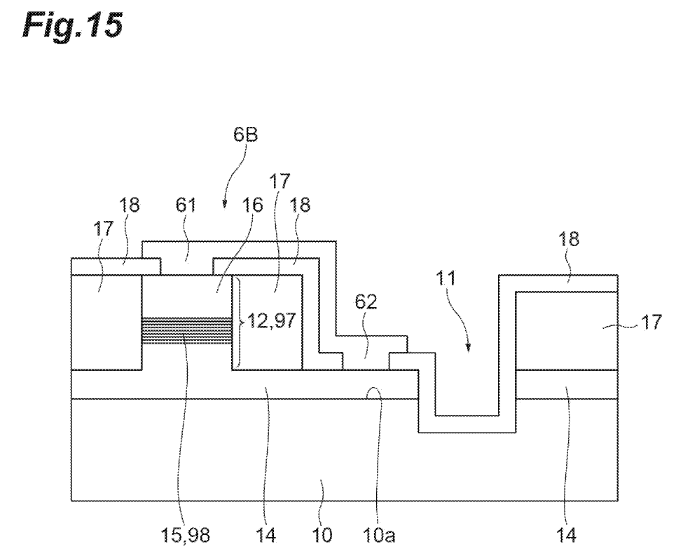

FIG. 14 is a plan view showing a laser device 1E according to a fourth modification of the above embodiment. FIG. 15 is a drawing schematically showing a cross section taken along the line XV-XV shown in FIG. 14. The laser device 1E according to this modification is different from the laser device 1D according to the third modification in the following points, but is the same as the laser device 1D in other points.

The laser device 1E according to this modification includes a potential setting section 6B instead of the potential setting section 6A in the third modification. The potential setting section 6B is provided on the optical path between the laser unit 9 and the optical modulator 2A. The potential setting section 6B further includes an anode electrode 61 in addition to the cathode electrode 62. The anode electrode 61 and the cathode electrode 62 extend along the optical waveguide direction, are aligned in a direction crossing the optical waveguide direction, and are connected to each other. The anode electrode 61 is provided on the mesa structure of the potential setting section 6B, and is connected to the second cladding layer 16 of the potential setting section 6B. The anode electrode 61 is integrally connected to the anode electrode 91 of the laser unit 9. As a result, the anode electrode 61 and the cathode electrode 62 of the potential setting section 6B are set to the reference potential. The reference potential is transmitted to the first cladding layer 14 and the second cladding layer 16 of the potential setting section 6B.

According to the configuration of this modification, as in the third modification, it is possible to further increase the electrical isolation between the laser unit 9 and the optical modulator 2A.

### Fifth Modification

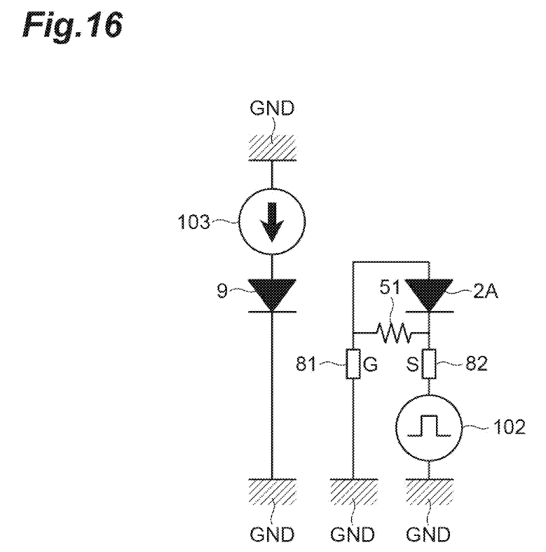

FIG. 16 is a circuit diagram showing a laser device according to a fifth modification of the above embodiment and its peripheral circuits. In this modification, a bias current source 103 that generates a bias current is connected between the anode of the laser unit 9 and the reference potential line GND. The cathode of the laser unit 9 is connected to the reference potential line GND. That is, a bias voltage having a potential higher than the reference potential is input to the anode electrode 91 of the laser unit 9. The reference potential is input to the cathode electrode 92 of the laser unit 9. As a result, a bias current flows between the anode electrode 91 and the cathode electrode 92. Other configurations excluding this point are the same as those of the above embodiment.

In this modification as well, since the first modulation signal is less likely to interfere with the bias current, wavelength fluctuations occurring in the laser light are reduced, and accordingly, it is possible to improve the quality of the optical signal.

### Sixth Modification

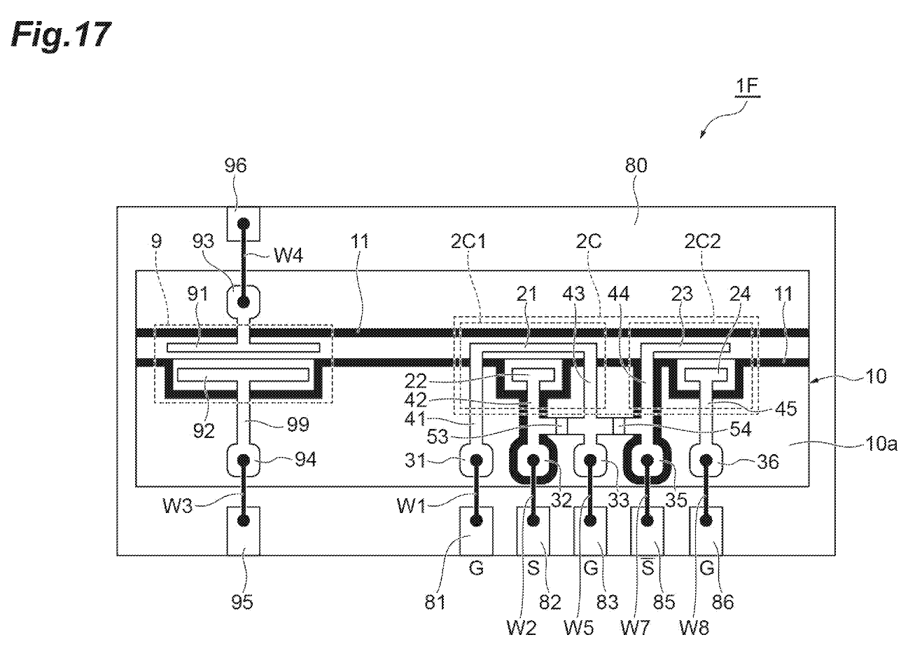

FIG. 17 is a plan view showing a laser device 1F according to a sixth modification of the above embodiment. The laser device 1F according to this modification is different from the laser device 1C according to the second modification in the following points, but is the same as the laser device 1C in other points. The laser device 1F includes an optical modulator 2C instead of the optical modulator 2A in the above embodiment. The optical modulator 2C is provided monolithically with the laser unit 9 on the substrate 10. The optical modulator 2C and the laser unit 9 are adjacent to each other along the optical waveguide direction on the substrate 10. The optical modulator 2C receives the laser light from the laser unit 9. The optical modulator 2C is an EA type optical modulator, and modulates the laser light output from the laser unit 9.

The optical modulator 2C includes a first optical modulator 2C1 and a second optical modulator 2C2. The configuration of the first optical modulator 2C1 is the same as that of the optical modulator 2A in the above embodiment. The second optical modulator 2C2 is provided at a stage following the first optical modulator 2C1, and modulates the laser light output from the first optical modulator 2C1 with a second modulation signal. The internal configuration of the second optical modulator 2C2 is the same as that of the first optical modulator 2C1 (that is, the optical modulator 2A).

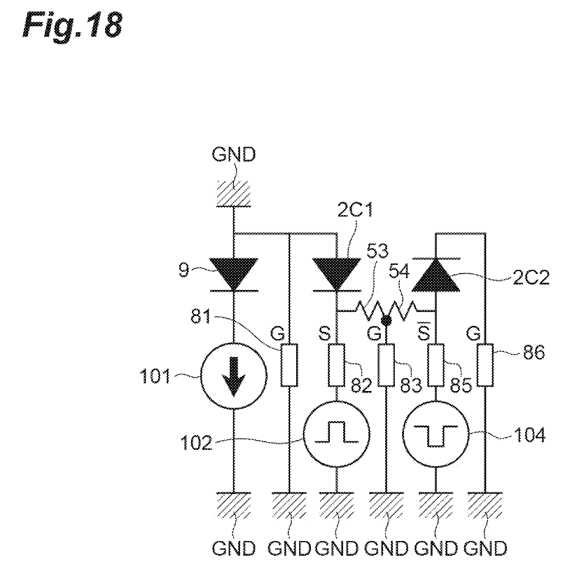

FIG. 18 is a circuit diagram showing the laser device 1F according to this modification and its peripheral circuits. In FIG. 18, the first optical modulator 2C1 and the second optical modulator 2C2 are indicated by diode symbols. As shown in FIG. 18, a signal source 102 that generates a first modulation signal is connected between the cathode of the first optical modulator 2C1 and the reference potential line GND. The signal source 102 supplies a first modulation signal having a potential higher than the potential of the reference potential line GND to the cathode of the first optical modulator 2C1 through the signal wiring pattern 82. The anode of the first optical modulator 2C1 is connected to the reference potential line GND through the ground wiring pattern 81. A signal source 104 that generates a second modulation signal is connected between the anode of the second optical modulator 2C2 and the reference potential line GND. The signal source 104 supplies a second modulation signal having a potential lower than the potential of the reference potential line GND to the anode of the second optical modulator 2C2 through a signal wiring pattern 85. The cathode of the second optical modulator 2C2 is connected to the reference potential line GND through a ground wiring pattern 86.

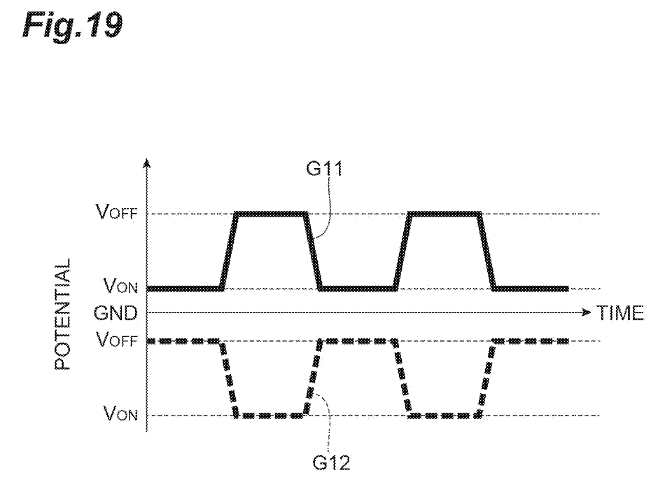

FIG. 19 is a graph showing the time waveforms of a first modulation signal G11 and a second modulation signal G12 applied to the optical modulator 2C. As shown in FIG. 19, the first modulation signal G11 changes between a potential V_{OFF} and a potential V_{ON} that is lower than the potential V_{OFF}. The first optical modulator 2C1 absorbs the laser light when the first modulation signal G11 has the potential V_{ON}, and allows the laser light to pass therethrough when the first modulation signal G11 has the potential V_{OFF}. The potential V_{OFF} and the potential V_{ON} of the first modulation signal G11 are higher than the reference potential (indicated as GND in the drawing). The reference potential is, for example, 0.0 V. The second modulation signal G12 changes between a potential V_{OFF} and a potential V_{ON} that is lower than the potential V_{OFF}. The second optical modulator 2C2 absorbs the laser light when the second modulation signal G12 has the potential V_{ON}, and allows the laser light to pass therethrough when the second modulation signal G12 has the potential V_{OFF}. The potential V_{OFF} and the potential V_{ON} of the second modulation signal G12 are lower than the reference potential (indicated as GND in the drawing). The second modulation signal G12 and the first modulation signal G11 form a differential signal. That is, the first modulation signal G11 is a positive-phase signal, and the second modulation signal G12 is an inverted-phase signal.

FIG. 17 is referred to again. The second optical modulator 2C2 has an anode electrode 23 instead of the anode electrode 21 and a cathode electrode 24 instead of the cathode electrode 22. The anode electrode 23 is provided on the mesa structure 12 of the second optical modulator 2C2, and is connected to the second cladding layer 16 of the second optical modulator 2C2. The cathode electrode 24 is provided on a lateral side of the mesa structure 12 of the second optical modulator 2C2, and is connected to the first cladding layer 14 of the second optical modulator 2C2.

The laser device 1F according to this modification further includes an electrode pad 35 (fifth electrode pad) and an electrode pad 36 (sixth electrode pad) provided on the substrate 10. The electrode pads 35 and 36 are provided on one side (the same side as the electrode pads 31, 32, and 33) of the optical modulator 2C. The electrode pads 94, 31, 32, 33, 35, and 36 are aligned in this order along the optical waveguide direction. A signal wiring pattern 85 and a ground wiring pattern 86 are further provided on the carrier 80. The electrode pad 35 is connected to the anode electrode 23 through a wiring 44 that is a metal film, and is also connected to the signal wiring pattern 85 through a bonding wire W7. The electrode pad 36 is connected to the cathode electrode 24 through a wiring 45 that is a metal film, and is also connected to the ground wiring pattern 86 through a bonding wire W8. The wirings 44 and 45 extend in a direction crossing the optical waveguide direction, and extend in parallel with the wirings 41, 42, and 43. The wiring 44 is arranged between the wiring 43 and the wiring 45 in the optical waveguide direction. A second modulation signal is input to the electrode pad 35 from the signal wiring pattern 85 through the bonding wire W7. The reference potential is input to the electrode pad 36 from the ground wiring pattern 86 through the bonding wire W8.

A termination resistor 54 (second terminator) is provided between the wiring 43 and the wiring 44. The wiring 44 is connected to the wiring 43 through the termination resistor 54, and the termination resistor 54 has a second resistive film. Instead of the termination resistor 52 in the second modification, a termination resistor 53 (first terminator) is provided between the wiring 42 and the wiring 43. The termination resistor 53 has a first resistive film. The wiring 42 is connected to the wiring 43 through the termination resistor 53. The arrangement of the termination resistors 53 and 54 is not limited to this modification. For example, the termination resistors 53 and 54 may be provided on the carrier 80. Each of the termination resistors 53 and 54 may be replaced with a CR circuit having a complex impedance.

When viewed in the thickness direction of the substrate 10, a trench 11 is formed between a region of the semiconductor layer overlapping the electrode pad 35 and a region of the semiconductor layer surrounding the electrode pad 35. The trench 11 completely surrounds the electrode pad 35 when viewed in the thickness direction of the substrate 10. The wiring 44 crosses the trench 11 by running along a sidewall and a bottom surface of the trench 11 between the electrode pad 35 and the anode electrode 23.

According to this modification, as in the above embodiment, interference of the first modulation signal with the bias current is suppressed, and the quality of the optical signal can be improved. As in the laser device 1F according to this modification, a laser device may further include: an electro-absorption type second optical modulator 2C2 provided at a stage following the first optical modulator 2C1 on the substrate 10; an electrode pad 35 provided on the substrate 10 and connected to the anode electrode 23 of the second optical modulator 2C2; and an electrode pad 36 provided on the substrate 10 and connected to the cathode electrode 24 of the second optical modulator 2C2. As described above, the reference potential is input to the electrode pad 36. A second modulation signal, which has a potential lower than the reference potential and forms a differential signal together with the first modulation signal, is input to the electrode pad 35. In this case, electrical interference with the laser unit 9 is further reduced, and the degradation of signal quality due to common-mode noise can be reduced. Therefore, it is possible to further improve the quality of the optical signal output from the laser device 1F.

As in this modification, the trench 11 reaching the substrate 10 may be formed between the region of the semiconductor layer overlapping the electrode pad 35 and the region of the semiconductor layer surrounding the electrode pad 35 when viewed in the thickness direction of the substrate 10. This makes it easier for the cathode of the second optical modulator 2C2 and the cathode of the laser unit 9 to be electrically isolated from each other by the trench 11. Therefore, the interference of the second modulation signal with the bias current is suppressed, and the quality of the optical signal can be further improved.

### Seventh Modification

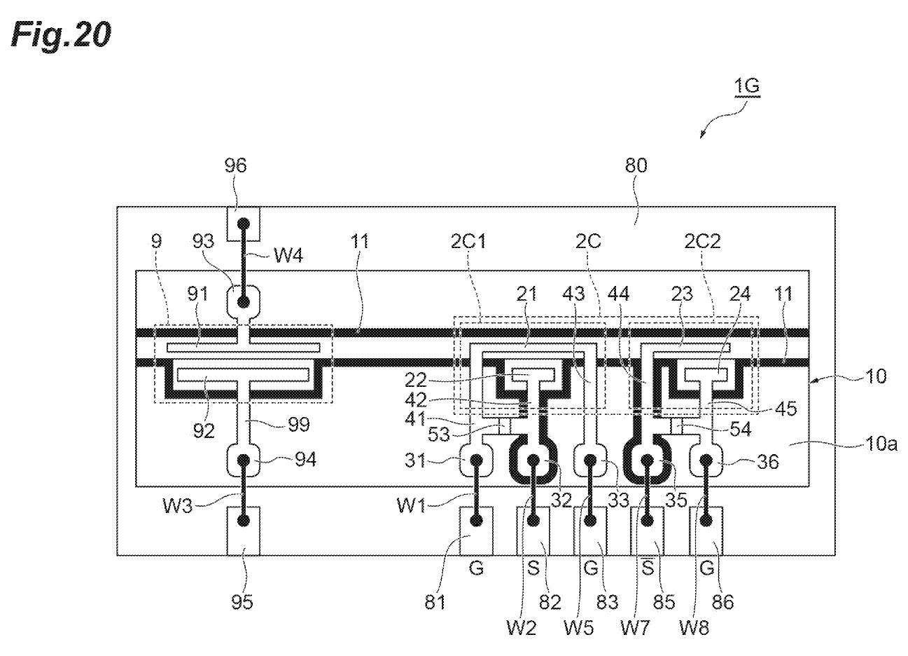

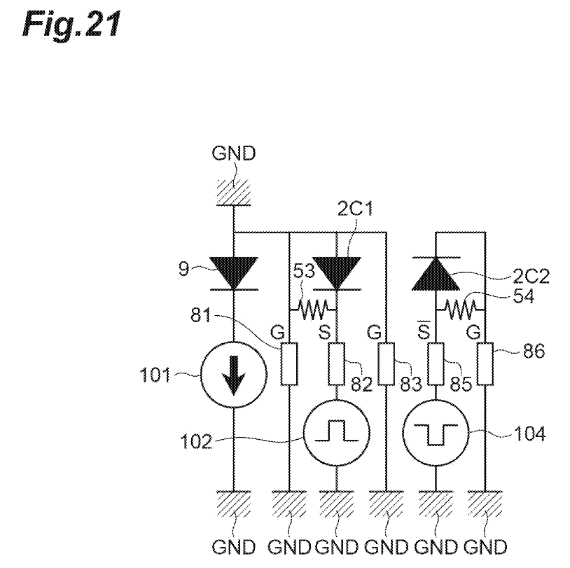

The laser device 1F according to the sixth modification described above can be modified as follows. FIG. 20 is a plan view showing a laser device 1G according to a seventh modification. FIG. 21 is a circuit diagram showing the laser device 1G according to this modification and its peripheral circuits. The laser device 1G according to this modification is different from the laser device 1F according to the sixth modification in the arrangement of the termination resistors 53 and 54, but is the same as the laser device 1F according to the sixth modification in other points. As shown in FIG. 20, the termination resistor 53 may be connected between the wiring 41 and the wiring 42. The termination resistor 54 may be connected between the wiring 44 and the wiring 45. Even in this configuration, the same effects as those in the sixth modification can be obtained.

### Eighth Modification

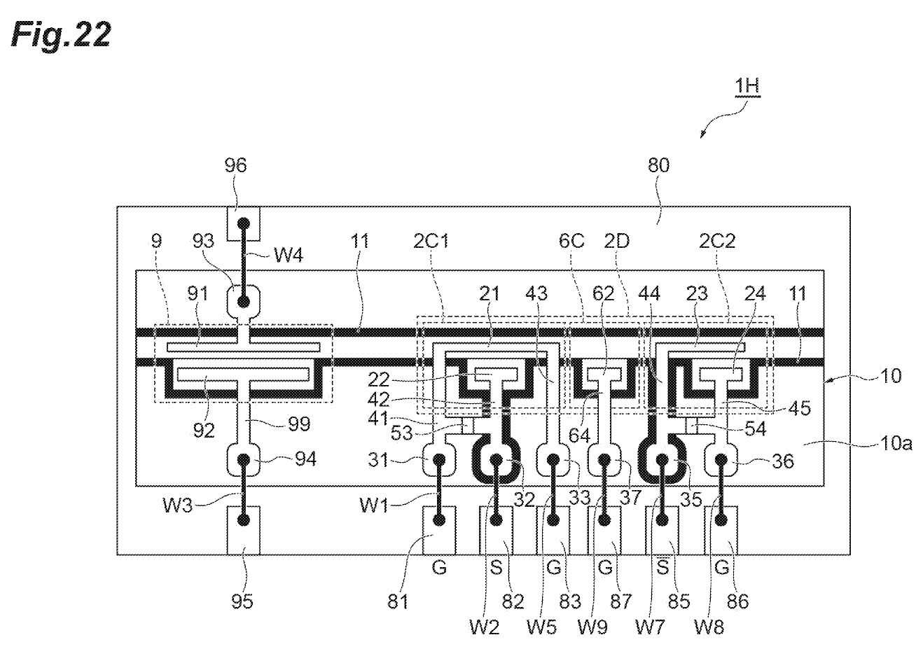

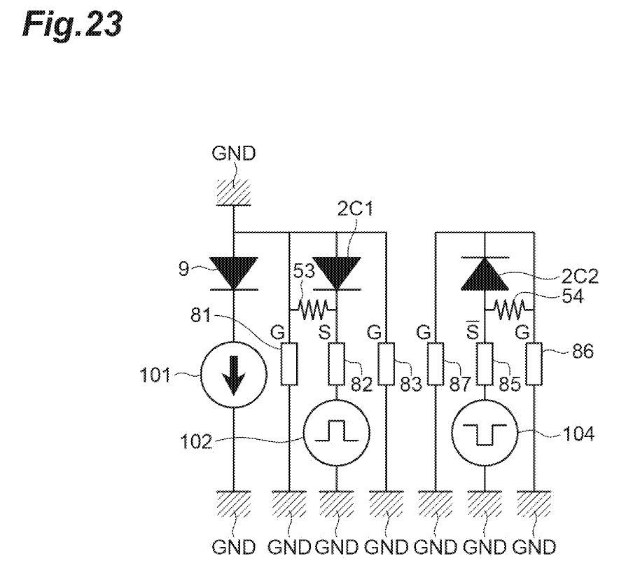

FIG. 22 is a plan view showing a laser device 1H according to an eighth modification of the above embodiment. FIG. 23 is a circuit diagram showing the laser device 1H according to this modification and its peripheral circuits. The laser device 1H according to this modification is different from the laser device 1G according to the seventh modification in the following points, but is the same as the laser device 1G in other points. The laser device 1H includes an optical modulator 2D instead of the optical modulator 2C in the seventh modification. The optical modulator 2D is provided monolithically with the laser unit 9 on the substrate 10. The optical modulator 2D and the laser unit 9 are adjacent to each other along the optical waveguide direction on the substrate 10. The optical modulator 2D receives the laser light from the laser unit 9. The optical modulator 2D is an EA type optical modulator, and modulates the laser light output from the laser unit 9.

The optical modulator 2D includes a first optical modulator 2C1, a second optical modulator 2C2, and a potential setting section 6C. The configurations of the first optical modulator 2C1 and the second optical modulator 2C2 are the same as those in the sixth modification. The potential setting section 6C is provided on the optical path between the first optical modulator 2C1 and the second optical modulator 2C2. The configuration of the potential setting section 6C is the same as that of the potential setting section 6A in the third modification.

The laser device 1H further includes an electrode pad 37. The electrode pad 37 is a metal film provided on one side (that is, the same side as the electrode pads 32 and 35) of the potential setting section 6C on the substrate 10. The electrode pad 37 is connected to the cathode electrode 62 of the potential setting section 6C through a wiring 64 that is a metal film. The wiring 64 extends in a direction crossing the optical waveguide direction, and runs parallel to the wirings 42, 44, and 99. The wiring 64 is arranged between the wiring 42 and the wiring 44 in the optical waveguide direction.

A ground wiring pattern 87 is further provided on the main surface of the carrier 80. The electrode pad 37 is connected to the ground wiring pattern 87 through a bonding wire W9. The reference potential is input to the electrode pad 37 from the ground wiring pattern 87 through the bonding wire W9. As a result, the cathode electrode 62 is set to the reference potential.

The electrode pad 37 is arranged between the electrode pad 33 and the electrode pad 35 on one side of the potential setting section 6C. That is, the electrode pads 94, 31, 32, 33, 37, 35, and 36 are aligned in this order along the optical waveguide direction. Therefore, the bonding wires W5 and W9, which are set to the reference potential, are located between the bonding wire W2 for transmitting the first modulation signal and the bonding wire W7 for transmitting the second modulation signal. The bonding wires W2, W5, W9, and W7 extend in parallel with each other.

As in this modification, the potential setting section 6C may be provided on the optical path between the first optical modulator 2C1 and the second optical modulator 2C2, and the potential of the first cladding layer 14 of the potential setting section 6C may be set to the reference potential. In this case, it is possible to further increase the electrical isolation between the first cladding layer 14 of the first optical modulator 2C1 to which the first modulation signal is applied and the first cladding layer 14 of the second optical modulator 2C2 to which the second modulation signal is applied.

In addition, in this modification, two electrode pads 33 and 37 for transmitting the reference potential are arranged between the electrode pad 32 for transmitting the first modulation signal and the electrode pad 35 for transmitting the second modulation signal. For this reason, two bonding wires W5 and W9 for transmitting the reference potential are inevitably arranged between the bonding wire W2 for transmitting the first modulation signal and the bonding wire W7 for transmitting the second modulation signal. In addition, two wirings 43 and 64 for transmitting the reference potential are arranged between the wiring 42 for transmitting the first modulation signal and the wiring 44 for transmitting the second modulation signal. Therefore, the quality of the first modulation signal and the second modulation signal is improved, and the quality of the optical signal can be further improved.

### Ninth Modification

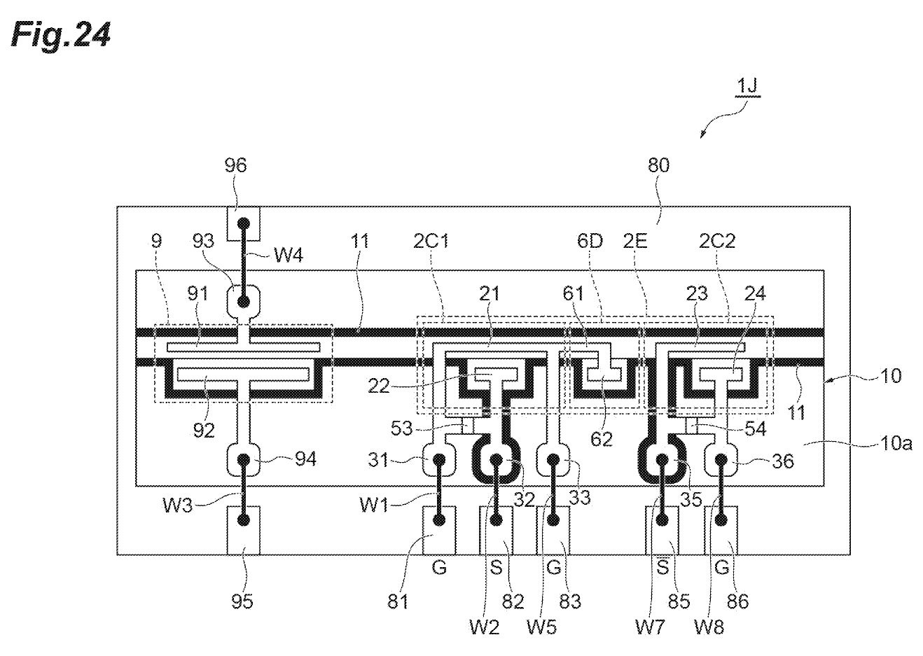

FIG. 24 is a plan view showing a laser device 1J according to a ninth modification. The laser device 1J according to this modification is different from the laser device 1H according to the eighth modification in the following points, but is the same as the laser device 1H in other points.

The laser device 1J according to this modification includes an optical modulator 2E instead of the optical modulator 2D of the eighth modification. The optical modulator 2E has a potential setting section 6D instead of the potential setting section 6C of the eighth modification. The potential setting section 6D is provided on the optical path between the first optical modulator 2C1 and the second optical modulator 2C2. The potential setting section 6D has a configuration similar to that of the potential setting section 6B (see FIG. 14) in the fourth modification. However, the anode electrode 61 is integrally connected to the anode electrode 21 of the first optical modulator 2C1. As a result, the anode electrode 61 and the cathode electrode 62 of the potential setting section 6D are set to the reference potential. The reference potential is transmitted to the first cladding layer 14 and the second cladding layer 16 of the potential setting section 6D.

According to the configuration of this modification, as in the eighth modification, it is possible to further increase the electrical isolation between the first optical modulator 2C1 and the second optical modulator 2C2.

### Tenth Modification

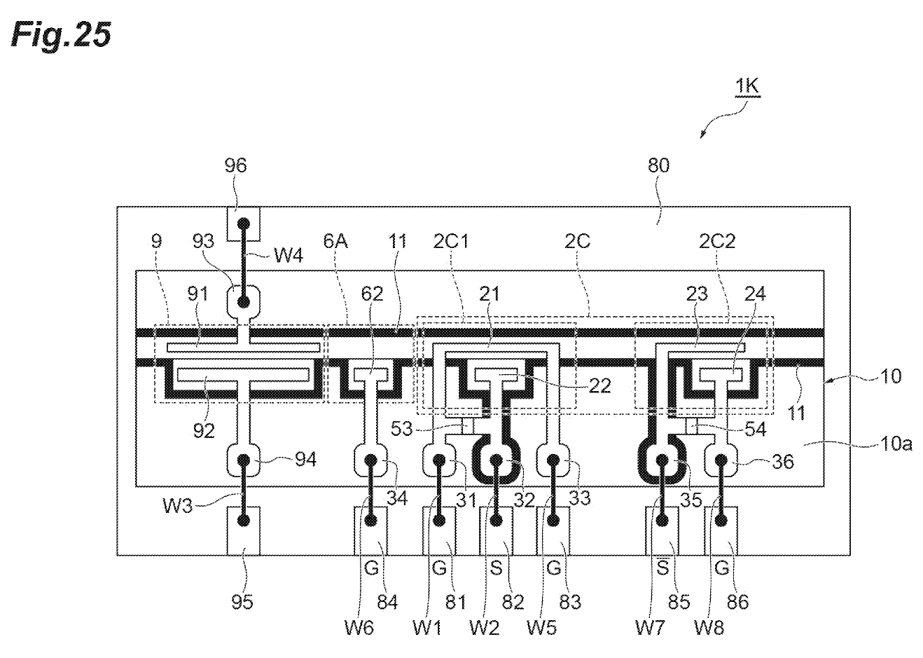

FIG. 25 is a plan view showing a laser device 1K according to a tenth modification. The laser device 1K according to this modification is different from the laser device 1G according to the seventh modification (see FIG. 20) in the following points, but is the same as the laser device 1G in other points. The laser device 1K further includes a potential setting section 6A and an electrode pad 34 provided on the substrate 10. The potential setting section 6A is provided on the optical path between the laser unit 9 and the optical modulator 2C. The configurations of the potential setting section 6A and the electrode pad 34 are the same as those of the third modification.

As in this modification, the potential setting section 6A may be provided on the optical path between the laser unit 9 and the optical modulator 2C, and the potential of the first cladding layer 14 of the potential setting section 6A may be set to the reference potential. In this case, it is possible to further increase the electrical isolation between the first cladding layer 14 of the laser unit 9 to which the bias voltage is applied and the first cladding layer 14 of the first optical modulator 2C1 to which the first modulation signal is applied. In addition, since the first modulation signal is more effectively shielded by the reference potential lines, the first modulation signal is even less likely to interfere with the bias current. As a result, wavelength fluctuations occurring in the laser light are further reduced, and accordingly, it is possible to further improve the quality of the optical signal.

### Eleventh Modification

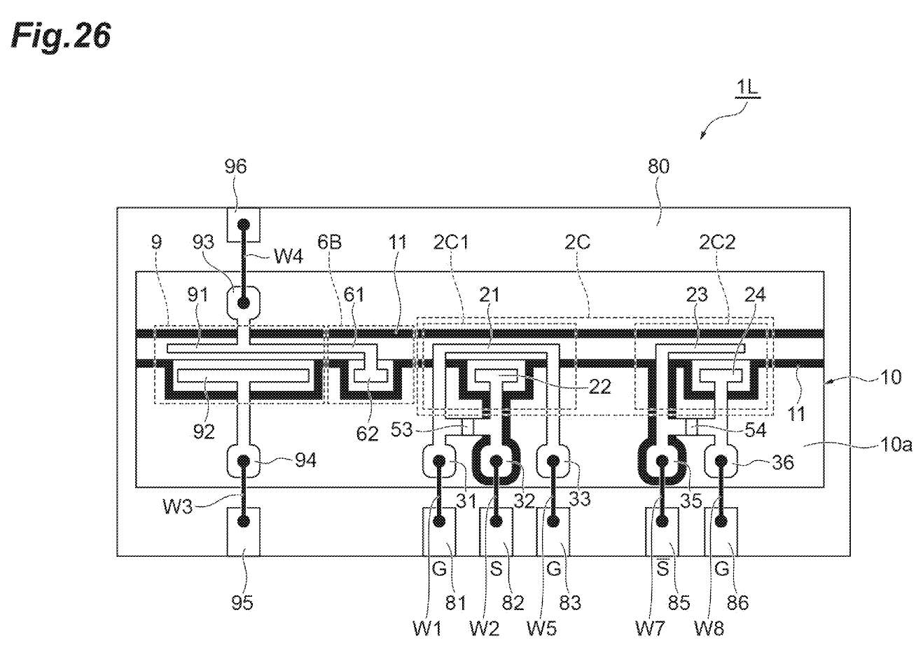

FIG. 26 is a plan view showing a laser device 1L according to an eleventh modification of the above embodiment. The laser device 1L according to this modification is different from the laser device 1K according to the tenth modification in the following points, but is the same as the laser device 1K in other points. The laser device 1L according to this modification includes a potential setting section 6B instead of the potential setting section 6A of the tenth modification. The configuration of the potential setting section 6B is the same as that in the fourth modification (see FIG. 14). According to the configuration of this modification, as in the tenth modification, it is possible to further increase the electrical isolation between the laser unit 9 and the optical modulator 2C.

The optical modulator integrated laser device according to the present disclosure is not limited to the above-described embodiment and its modifications, and various other modifications are possible. For example, the above-described embodiment and its modifications may be combined with each other in any combination.

In the above-described embodiment and its modifications, an InP-based semiconductor is exemplified as the III-V compound semiconductor that is a constituent material of the first cladding layer 14, the light absorption layer 15, and the second cladding layer 16, but the III-V compound semiconductor is not limited thereto. In the above-described embodiment and its modifications, a silicon compound film such as SiO2 or SiN is exemplified as the constituent material of the insulating film 18, but the constituent material (composition) of the insulating film 18 is not limited thereto. For example, the constituent material of the insulating film 18 may be a silicon oxide or a silicon nitride having a composition other than those in the embodiment and its modifications, or may be a silicon oxynitride.

In the above-described embodiment and its modifications, the optical modulator integrated laser device may further include a semiconductor optical amplifier provided on the substrate 10. As a result, compared with a case where the semiconductor optical amplifier is provided outside the substrate 10, it is possible to reduce the size of an apparatus including the optical modulator integrated laser device.

In the embodiment and its modifications, an electro-absorption (EA) type optical modulator formed of an InP-based semiconductor is exemplified as the optical modulator, but the configuration of the present disclosure can also be adopted for an optical modulator (silicon photonics) formed of an Si-based semiconductor.

In the above embodiment, the trench 11 reaching the substrate 10 is formed between the region of the semiconductor layer overlapping the electrode pad 32 and the region of the semiconductor layer surrounding the electrode pad 32. Without being limited to such a configuration, the trench 11 does not have to be formed to surround the electrode pad 32. Similarly, in the sixth modification, the trench 11 reaching the substrate 10 is formed between the region of the semiconductor layer overlapping the electrode pad 35 and the region of the semiconductor layer surrounding the electrode pad 35. Without being limited to such a configuration, the trench 11 does not have to be formed to surround the electrode pad 35.

When the optical modulator in the present embodiment is differentially driven, a configuration may be adopted in which one of the differential modulation signals is input to the anode electrode and the other of the differential modulation signals is input to the cathode electrode.

What is claimed is:

1. An optical modulator integrated laser device, comprising:
a laser unit that is provided on a substrate and configured to outputs laser light; and
an electro-absorption type first optical modulator that is provided on the substrate and configured to modulate the laser light output from the laser unit with a first modulation signal,
wherein the laser unit has an anode electrode to which a reference potential is input and a cathode electrode to which a bias voltage having a potential lower than the reference potential is input.

2. The optical modulator integrated laser device according to claim 1,
wherein the first optical modulator has an anode electrode to which the reference potential is input and a cathode electrode to which the first modulation signal is input.

3. The optical modulator integrated laser device according to claim 2,
wherein a trench reaching the substrate is formed to surround the cathode electrode of the first optical modulator.

4. The optical modulator integrated laser device according to claim 2,
wherein the laser unit and the first optical modulator are optically coupled by an optical waveguide, and
the anode electrode of the laser unit is connected to the anode electrode of the first optical modulator on the optical waveguide.

5. The optical modulator integrated laser device according to claim 1,
wherein an electrode pad having the reference potential is arranged between the laser unit and the first optical modulator.

6. The optical modulator integrated laser device according to claim 2, further comprising:
a first terminator provided on the substrate and having a first resistive film,
wherein the first terminator is connected between the anode electrode of the first optical modulator and the cathode electrode of the first optical modulator.

7. The optical modulator integrated laser device according to claim 1, further comprising:
an electro-absorption type second optical modulator provided on the substrate downstream of the first optical modulator,
wherein the second optical modulator has an anode electrode to which a second modulation signal forming a differential signal together with the first modulation signal is input and a cathode electrode to which the reference potential is input.

8. The optical modulator integrated laser device according to claim 7,
wherein a trench reaching the substrate is formed around the anode electrode of the second optical modulator.

9. The optical modulator integrated laser device according to claim 7, further comprising:
a second terminator provided on the substrate and having a second resistive film,
wherein the second terminator is connected between the anode electrode of the second optical modulator and the cathode electrode of the second optical modulator.

10. The optical modulator integrated laser device according to claim 1,
wherein the first optical modulator has an anode electrode to which one of differential modulation signals is input and a cathode electrode to which another of the differential modulation signals is input.
